(19) United States
(12) Patent Application Publication
(10) Pub. No.: US 2024/0270109 A1
(43) Pub. Date: Aug. 15, 2024

(54) DIAGNOSTIC METHOD OF A CHARGING STATION SYSTEM FOR AN ELECTRICAL VEHICLE AND CHARGING STATION SYSTEM FOR AN ELECTRIC VEHICLE

(71) Applicant: Schneider Electric Industries SAS, Rueil Malmaison (FR)

(72) Inventor: Stefano De Cesaris, Grenoble (FR)

(73) Assignee: Schneider Electric Industries SAS, Rueil Malmaison (FR)

(21) Appl. No.: 18/437,530

(22) Filed: Feb. 9, 2024

(30) Foreign Application Priority Data
Feb. 14, 2023 (FR) 2301353
Mar. 28, 2023 (FR) 2302950

(51) Int. Cl. B60L 53/62; B60L 53/16; B60L 53/18; B60L 53/66; B60L 55/00

(52) U.S. Cl. CPC B60L 53/62; B60L 53/16; B60L 53/18; B60L 53/66; B60L 55/00

(57) ABSTRACT

A charging station system for an electric vehicle includes two plugs, each configured to allow an electric vehicle to be charged by supplying it with direct current, two conductors, each one associated with a plug, and two groups of power modules, each one associated with a plug and capable of converting a current originating from an electric network into direct current delivered to the associated plug. A diagnostic method of the charging station system includes a connection step, aimed at connecting the two plugs together so as to form a loop including the two plugs, the two conductors and the two groups of power modules; a testing step, involving transmitting an electric quantity flowing between the two plugs, in the loop, and measuring operating states of at least some of the elements of the loop in response to this electric quantity; and an analysis step involving diagnosing the elements based on operating state measurements.

### TECHNICAL FIELD

The present invention relates to a diagnostic method for a charging station system for an electric vehicle and to a charging station system for an electric vehicle implementing such a diagnostic method.

### BACKGROUND

It is known for a charging station to be used in order to charge the battery of an electric vehicle, such as, for example, an electric car or an electric truck.

Generally, such a charging station comprises the following components:
one or more power modules, which convert an alternative or direct current originating from an electric network into direct current, and which are generally capable of supplying power ranging up to several tens of kilowatts;
a plug, connected to the power modules by a conductor, which allows a connection to be established between the power modules and an electric vehicle, so as to supply the electric vehicle with the direct current produced by the power modules; and
a control unit, which controls the operation of the plug.

Furthermore, a charging station generally has communication means, controlled by the control unit, which allow operating data to be exchanged between the charging station and an electric vehicle connected to the plug, so as to monitor the charging of the electric vehicle.

The correct operation of such a charging station needs to be regularly checked to ensure that the power modules and/or the control components of the charging station are operating correctly, and also to ensure the integrity of the conductor and of the plug. Indeed, the conductor and the plug are perishable parts exposed to numerous stresses that can result in their deterioration, such as, for example, a failure in the isolation or a breakdown in the communication means.

Two different methods are known for diagnosing the correct operation of a charging station.

A first method involves connecting a test electric vehicle, the battery of which has been drained beforehand, to the charging station and using various sensors to monitor the charging of the electric vehicle. The disadvantage of this method is that it requires the availability of an electric vehicle with a battery that has already been drained, which is logistically complex and expensive.

A second method involves connecting an electric load to the charging station that is capable of consuming the current produced by the power modules, so as to simulate the operation of an electric vehicle. Such an electric load is generally bulky, heavy and expensive, making it difficult to move and making this second method equally complex and expensive.

### SUMMARY

The invention is more specifically intended to overcome these disadvantages by proposing a diagnostic method for a charging station system for an electric vehicle that does not require complex equipment in order to be implemented, and that is simple and inexpensive to execute.

To this end, the invention relates to a diagnostic method for a charging station system for an electric vehicle, the charging station system comprising:
at least one first plug and one second plug, each plug comprising a positive connection point and a negative connection point, each plug being configured to allow an electric vehicle to be electrically connected to the charging station system and to allow the electric vehicle to be supplied with a direct current so as to charge the electric vehicle;
at least one first conductor, associated with the first plug, and one second conductor, associated with the second plug, each conductor comprising a positive polarity cable and a negative polarity cable; and
at least one first group of power modules associated with the first conductor and the first plug and one second group of power modules associated with the second conductor and the second plug, each group of power modules being capable of converting an alternative current or a direct current originating from an electric network into a direct current delivered to the associated plug by means of the associated conductor.

According to the invention, the diagnostic method comprises at least the following steps:
a connection step, involving connecting the positive connection point of the first plug with the positive connection point of the second plug and connecting the negative connection point of the first plug with the negative connection point of the second plug, so as to form a loop comprising at least:
   the first and second plugs;
   the first and second conductors; and
   the first and second groups of power modules;
a testing step, involving transmitting at least one electric quantity flowing at least from the first plug to the second plug and measuring operating states of at least some of the elements of the loop in response to the transmitted electric quantity; and
an analysis step, involving diagnosing said elements on the basis of the measurements of the operating states.

By virtue of the invention, it is possible to diagnose a charging station system comprising a charging station with two plugs, or even comprising two charging stations each with one plug, simply by connecting the two plugs to each other. Thus, one portion of the charging station system simulates an electric vehicle, while the other portion of the charging station system acts as if it were charging an electric vehicle, allowing the charging station system to be diagnosed without requiring an external electric load or an electric vehicle.

According to advantageous but non-binding aspects of the invention, this diagnostic method for a charging station system for an electric vehicle incorporates one or more of the following features, taken alone or in any technically permissible combinations:

The charging station system further comprises:
a first isolation control device connected to the positive polarity cable and to the negative polarity cable of the first conductor, as well as to an earth plug, and capable of carrying out an impedance computation between:
   said positive polarity cable and said earth plug;
   said negative polarity cable and said earth plug; and/or
   said positive polarity cable and said negative polarity cable; and
a second isolation control device connected to the positive polarity cable and to the negative polarity cable of the second conductor, as well as to an earth plug, and capable of carrying out an impedance computation between:
   said positive polarity cable and said earth plug;
   said negative polarity cable and said earth plug; and/or
   said positive polarity cable and said negative polarity cable;
      the charging station system further comprises isolation components that are either disposed in the second group of power modules or are disposed in the second conductor between the second group of power modules and the second isolation control device,
      the isolation components can be operated between an open position, in which the flow of a voltage and a current between the second group of power modules and the second isolation control device is prevented, and a closed position, in which the flow of a voltage and a current between the second group of power modules and the second isolation control device is not prevented,
      the testing step further comprises an opening phase involving keeping the isolation components in the open position,
      the at least one electric quantity transmitted during the testing step comprises a test signal, transmitted during the opening phase by the first isolation control device in the first conductor and flowing in the loop to the isolation components, by means of the first plug and the second plug,
      during the analysis step, a diagnostic of the integrity of the isolation of the first and second conductors and of the reliability of the first and second isolation control devices is carried out by comparing:
an impedance value between the positive polarity cable of the first conductor and the earth plug of the first isolation control device with an impedance value between the positive polarity cable of the second conductor and the earth plug of the second isolation control device, with the impedance values being computed during the opening phase by the first and second isolation control devices on the basis of the test signal; and/or
an impedance value between the negative polarity cable of the first conductor and the earth plug of the first isolation control device with an impedance value between the negative polarity cable of the second conductor and the earth plug of the second isolation control device, with the impedance values being computed during the opening phase by the first and second isolation control devices on the basis of the test signal; and/or
an impedance value between the positive and negative polarity cables of the first conductor with an impedance value between the positive and negative polarity cables of the second conductor, with the impedance values being computed during the opening phase by the first and second isolation control devices on the basis of the test signal.
   The charging station system comprises an upstream voltmeter, adapted to measure a voltage at the output terminals of the second group of power modules,
the charging station system further comprises isolation components that are either disposed in the second group of power modules or are disposed in the second conductor between the second group of power modules and the second plug;
the isolation components can be operated between an open position, in which the flow of a voltage and a current between the second group of power modules and the second plug is prevented, and a closed position, in which the flow of a voltage and a current between the second group of power modules and the second plug is not prevented,
the testing step further comprises an opening phase involving keeping the isolation components in the open position,
the at least one electric quantity transmitted during the testing step comprises a direct voltage, transmitted during the opening phase by the first group of power modules and flowing in the loop to the isolation components, by means of the first plug and the second plug,
the testing step comprises, during the opening phase, a voltage measurement carried out by the upstream voltmeter, and
   the analysis step further comprises diagnosing the operation of the isolation components, carried out by checking whether the voltage measured by the upstream voltmeter during the opening phase is zero.
   The second conductor further comprises a downstream voltmeter, disposed between the isolation components and the second plug, adapted to measure a voltage between the positive polarity cable and the negative polarity cable of the second conductor,
the testing step further comprises a closing phase involving keeping the isolation components in the closed position,
the at least one electric quantity transmitted during the testing step further comprises a direct voltage, transmitted during the closing phase by the first group of power modules and flowing in the loop to the second group of power modules, by means of the first plug and the second plug, and
   during the analysis step, a diagnostic of the integrity of the isolation components of the second conductor is carried out by comparing a voltage measured by the upstream voltmeter during the closing phase with a voltage measured by the downstream voltmeter during the closing phase.
   The charging station system further comprises at least one first control unit associated with the first plug and one second control unit associated with the second plug, each control unit controlling the operation of the associated plug,
the first plug and the second plug each further comprise communication means connected to the associated control unit and configured so as to allow, when a plug is electrically connected to an electric vehicle, communication between an electric vehicle and the control unit associated with said plug,
during the connection step, the communication means of the first plug are connected to the communication means of the second plug,
the at least one electric quantity transmitted during the testing step comprises a communication signal, transmitted by the first control unit and flowing to the second control unit by means of the first plug and the second plug, and during the analysis step, a diagnostic of the integrity of the communication means of the first and second plugs and of the second control unit is carried out as follows:
by comparing the communication signal transmitted by the first control unit with the communication signal received by the second control unit; and/or
by analysing a response signal transmitted by the second control unit in response to the receipt of the communication signal.
   The first and second groups of power modules are further capable of converting direct current originating from the associated plug into an alternative current or a direct current suitable for being delivered to the electric network, and
   the at least one electric quantity transmitted during the testing step comprises a direct current, transmitted by the first group of power modules and flowing in the loop to the second group of power modules, by means of the first plug and the second plug, the direct current received by the second group of power modules being converted into an alternative current or into a direct current suitable for being delivered to the electric network.
   The charging station system further comprises an input power switch and a distribution system, the input power switch being configured to allow the distribution system to be connected to the electric network, and the distribution system being configured to connect the first and second groups of power modules to each other and to the input power switch, the second group of power modules also being capable of converting a direct current originating from the charging station system into an alternative current or into a direct current delivered to the first group of power modules,
during the testing step, the direct current received by the second group of power modules is converted by the second group of power modules into alternative current or into direct current delivered to the first group of power modules by means of the distribution system,
during the testing step, the first group of power modules is powered with alternative current or direct current by the second group of power modules and by the electric network, and
   at least 90% of the electric power consumed by the first group of power modules during the testing step is delivered to the first group of power modules by the second group of power modules.
   The charging station system further comprises:
a first electricity meter disposed between the first group of power modules and the first plug and adapted to measure a voltage and an intensity of the direct current flowing in the first conductor;
a second electricity meter disposed between the second group of power modules and the second plug and adapted to measure a voltage and an intensity of the direct current flowing in the second conductor; and
   the analysis step comprises a diagnostic of the reliability of the electricity meters, carried out by comparing voltage and intensity measurements carried out by the first electricity meter during the testing step with voltage and intensity measurements carried out by the second electricity meter during the testing step.
   The charging station system further comprises:
a first temperature sensor disposed on the first plug or on the first conductor; and/or
a second temperature sensor disposed on the second plug or on the second conductor; and
   the analysis step comprises diagnosing overheating, carried out by analysing temperature measurements carried out by the first temperature sensor and/or by the second temperature sensor during the testing step.
   During the testing step, an electric power supplied by the first group of power modules to the second group of power modules by means of the direct current transmitted by the first group of power modules is at least 5% higher than a rated electric power of the second group of power modules, and
   the analysis step comprises diagnosing the overload resistance of the second group of power modules, carried out by analysing quantities characteristic of the operation of the second group of power modules measured during the testing step.

According to another aspect, the invention also relates to a charging station system for an electric vehicle comprising:
at least one first plug and one second plug, each plug comprising a positive connection point and a negative connection point, each plug being configured to allow an electric vehicle to be electrically connected to the charging station system and to allow the electric vehicle to be supplied with direct current so as to charge the electric vehicle;
at least one first conductor, associated with the first plug, and one second conductor, associated with the second plug, each conductor comprising a positive polarity cable and a negative polarity cable; and
at least one first group of power modules associated with the first conductor and the first plug and one second group of power modules associated with the second conductor and the second plug, each group of power modules being capable of converting an alternative current or a direct current originating from an electric network into a direct current delivered to the associated plug by means of the associated conductor.

According to the invention, the charging station system further comprises connection means adapted to connect the positive connection point of the first plug with the positive connection point of the second plug and to connect the negative connection point of the first plug with the negative connection point of the second plug, and the charging station system comprises a control module configured to execute the testing and analysis steps of the diagnostic method described above.

This charging station system has the same advantages as those described above with respect to the diagnostic method of the invention.

According to advantageous but non-binding aspects of the invention, this charging station system incorporates one or more of the following features, taken alone or in any technically permissible combinations:

The control module is physically connected to the first plug and/or to the second plug, or the control module is even integrated in a remote server.
The connection means are formed by a connection tool, such as a cable or a casing, having a first female end fitting adapted to be connected to the first plug and having a second female end fitting adapted to be connected to the second plug.
The charging station system comprises a single charging station comprising:
at least two power modules, each power module being capable of converting an alternative current or a direct current originating from the electric network into a direct current delivered to the charging station system;
at least one power distribution unit:
   comprising at least one first output terminal connected to the first conductor and one second output terminal connected to the second conductor;
   an output of each of the power modules being electrically coupled to the power distribution unit;
   the distribution unit being configured to be switchable so that each power module is either connected to the first output terminal or is connected to the second output terminal, or is isolated from the first and second output terminals;
      the one or more power modules connected to the first output terminal form the first group of power modules, and
      the one or more power modules connected to the second output terminal form the second group of power modules.
      The charging station system comprises:
a first charging station comprising the first plug, the first conductor and the first group of power modules; and
a second charging station separate from the first charging station, comprising the second plug, the second conductor and the second group of power modules.

### BRIEF DESCRIPTION OF THE DRAWINGS

The invention will be better understood and further advantages thereof will become more clearly apparent in the light of the following description of an embodiment of a diagnostic method for a charging station system for an electric vehicle and of a charging station system for an electric vehicle, which description is provided solely by way of an example and with reference to the appended drawings, in which:

FIG. 1 is an operating diagram of a charging station system for an electric vehicle according to the invention;

FIG. 2 is a larger-scale view of the detail II of FIG. 1;

FIG. 3 is a larger scale view of the detail Ill of FIG. 1.

### DETAILED DESCRIPTION

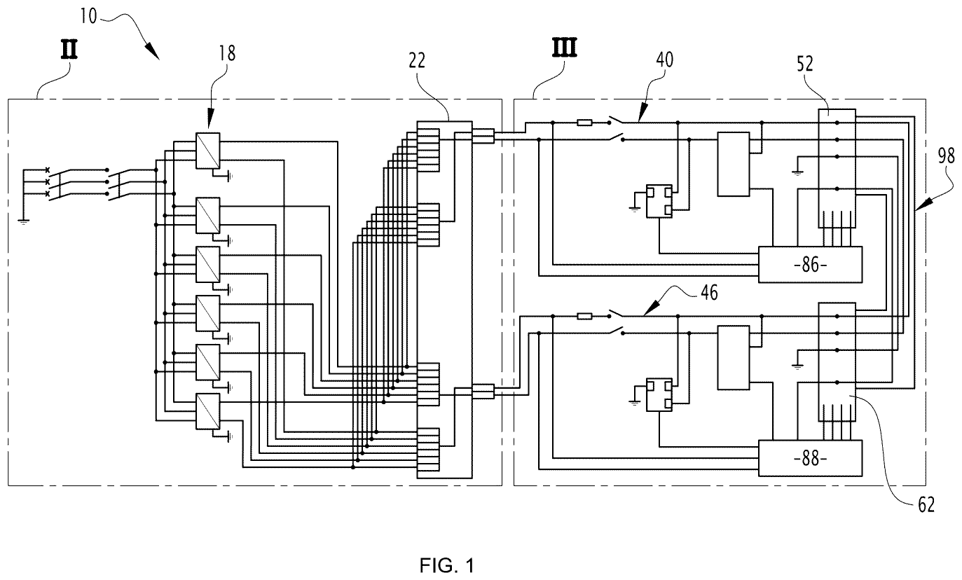

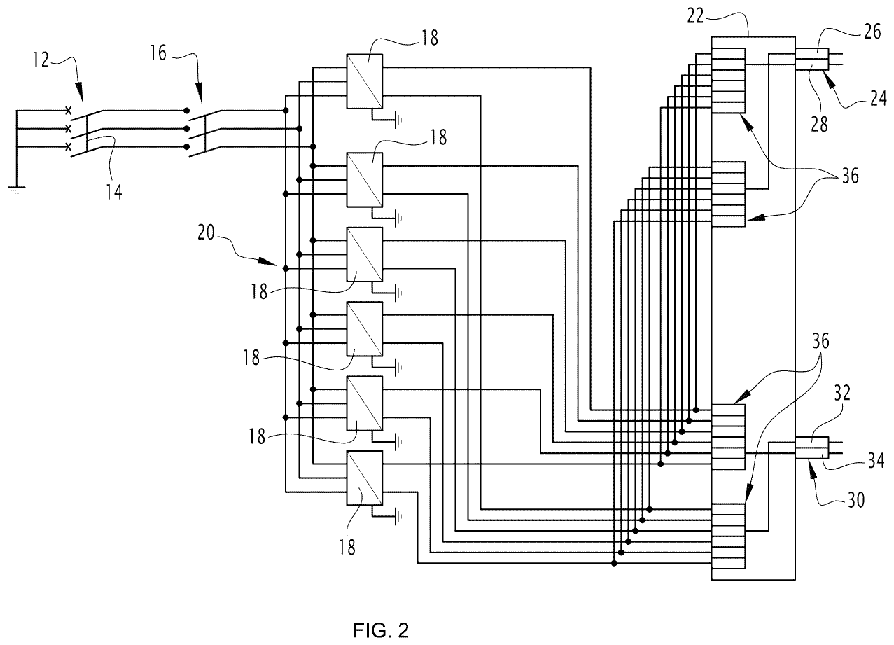

A charging station system 10 is schematically shown in FIGS. 1 to 3.

The charging station system 10 comprises an input terminal block 12 connected to an alternative electric network powering the charging station system. In this case, the alternative electric network is a three-phase network, therefore, the input terminal block 12 has three phases. The input terminal block 12 comprises a three-phase circuit breaker 14, capable of breaking the three phases and protecting these three phases from any electric faults.

The charging station system 10 comprises an input power switch 16 allowing the charging station system 10 to be disconnected from the electric network by disconnecting each of the phases.

The charging station system 10 comprises six power modules 18, as well as a distribution system 20, which is, for example, a busbar or a set of electric cables, and which connects each of the power modules 18 to each other and to the input power switch 16. Thus, the power modules 18 are all connected to the electric network, and therefore all powered with alternative current, by means of the distribution system 20 and the input power switch 16. Preferably, as a safety measure, each power module 18 is connected to an earth plug.

The charging station system 10 comprises a power distribution unit 22, to which the power modules 18 are connected.

Each power module 18 is capable of converting the alternative current originating from the electric network into a direct current delivered to the power distribution unit 22. In other words, each power module 18 can operate as an AC/DC converter, i.e., as a rectifier.

Throughout the remainder of the description, the terminals of the power modules 18 connected to the electric network are referred to as “input terminals”, and the terminals of the power modules connected to the power distribution unit 22 are referred to as “output terminals”.

Furthermore, each power module 18 includes an ammeter and a voltmeter, together forming an electricity meter, for measuring the voltage and the intensity of the direct current delivered by the power module to the power distribution unit 22, i.e., to the output terminals of the power module. In other words, the electric power of the direct current delivered by each power module 18 is measured by the electricity meter. Preferably, each power module 18 is capable of supplying the power distribution unit 22 with electric power ranging between 10 and 100 kilowatts (KW), for example, 30 kilowatts. Throughout the remainder of the description, the expression “rated power” is used to refer to the maximum electric power at which a power module 18 is designed to operate under normal operating conditions. Thus, the rated power of a power module 18 corresponds to the maximum power that this power module can safely deliver to the power distribution unit 22.

Preferably, all the power modules 18 are identical and therefore have the same rated power.

In addition, each power module 18 is controllable so as to adjust the power delivered to the power distribution unit 22. Thus, each power module is able to supply between 0% and 100% of its rated power to the power distribution unit.

Advantageously, each power module 18 is also capable of converting a direct current originating from the power distribution unit 22 into an alternative current injected into the electric network, i.e., each power module 18 can operate as an inverter. In other words, the power modules 18 are reversible. Preferably, under normal operating conditions, each power module is designed to be able to supply the electric network with a maximum electric power equal to the rated power of the power module.

The power distribution unit 22 comprises a first output terminal 24 comprising a positive polarity output 26 and a negative polarity output 28, and a second output terminal 30 comprising a positive polarity output 32 and a negative polarity output 34.

Each power module 18 comprises a negative output and a positive output.

By means of four groups of relays 36 of the power distribution unit 22, the positive polarity outputs 26, 32 of the output terminals 24, 30 are connected to the positive outputs of all the power modules 18, and the negative polarity outputs 28, 34 of the output terminals 24, 30 are connected to the negative outputs of all the power modules. Each group of relays 36 comprises as many relays as the power modules 18 of the charging station system.

More specifically, a first group of relays connects the positive output of each of the power modules 18 to the positive polarity output 26 of the first output terminal 24, a second group of relays connects the positive output of each of the power modules 18 to the positive polarity output 32 of the second output terminal 30, a third group of relays connects the negative output of each of the power modules 18 to the negative polarity output 28 of the first output terminal 24 and a fourth group of relays connects the negative output of each of the power modules 18 to the negative polarity output 34 of the second output terminal 30.

In practice, the positive and negative outputs of each power module 18 are connected to the groups of relays 36 of the power distribution unit 22 either by electric cables or by busbars.

Thus, the two output terminals 24, 30 are connected to all the power modules 18. In addition, the relays of the groups of relays 36 are switchable so that each power module 18 is either connected to the first output terminal 24, or is connected to the second output terminal 30, or is isolated from the first and second output terminals. In other words, the groups of relays 36 are switched so that a power module 18 cannot be simultaneously connected to both output terminals 24, 30, or even so that the positive polarity cable and the negative polarity cable of a power module cannot be connected to two different output terminals of the power distribution unit.

A distinction is then made between a first group of power modules, which comprises the power modules 18 connected to the first output terminal 24, a second group of power modules, which comprises the power modules 18 connected to the second output terminal 30, and a third group of power modules, which comprises the power modules 18 not connected to any output terminal. The power modules 18 of the same group of power modules are mounted in parallel, so that the voltage delivered by a group of power modules does not vary with the number of power modules belonging to this group, and so that the current delivered by a group of power modules corresponds to the sum of the current delivered by all the power modules of this group.

In practice, the first group of power modules can be assimilated into a single power module with a rated power that is equal to the sum of the rated powers of the power modules belonging to the first group. The same applies to the second group of power modules. Thus, measuring the voltage at the output terminals of a power module is equivalent to measuring the voltage at the output terminals of the group of power modules to which this module belongs.

The charging station system 10 comprises a first conductor 40, which comprises a positive polarity cable 42 connected to the positive polarity output 26 of the first output terminal 24, and a negative polarity cable 44 connected to the negative polarity output 28 of the first output terminal 24, as well as a second conductor 46, which comprises a positive polarity cable 48 connected to the positive polarity output 32 of the second output terminal 30, and a negative polarity cable 50 connected to the negative polarity output 34 of the second output terminal 30.

The charging station system 10 comprises a first plug 52, which comprises a positive connection point 54 and a negative connection point 56, respectively connected to the positive 42 and negative 44 polarity cable of the first conductor 40, as well as an earth connection point 58, connected to an earth plug.

The charging station system 10 comprises a second plug 62, which comprises a positive connection point 64 and a negative connection point 66, respectively connected to the positive 48 and negative 50 polarity cable of the second conductor 46, as well as an earth connection point 68, connected to an earth plug.

Thus, the first plug 52 and the second plug 62 are respectively connected to the first output terminal 24 and the second output terminal 30 of the power distribution unit 22.

Each of the first and second plugs 52, 62 is adapted to be connected to an electric vehicle, thereby allowing an electric vehicle to be electrically connected to the charging station system 10, and more specifically allowing a direct current to be supplied from the power distribution unit 22 to the electric vehicle in order to allow it to be charged. Thus, when an electric vehicle is connected to a plug 52, 62, the corresponding group of power modules delivers a direct current to the plug by means of the corresponding conductor 40, 46.

The first and second plugs 52, 62 are preferably in the form of male plugs, and comply, for example, with the “Combined Charging System” standard, more commonly referred to using the abbreviation “CCS”, or with the “CHAdeMO” standard. In another example, one of the two plugs 52, 62 complies with the CCS standard, while the other one of the two plugs complies with the CHAdeMO standard. The plugs 52, 62 can also comply with other standards not described herein.

By virtue of the presence of two separate plugs, the charging station system 10 allows two electric vehicles to be charged simultaneously. In practice, the power distribution unit 22 allocates the power modules 18 to the first group, to the second group and to the third group of power modules as a function of the electric power required to charge electric vehicles plugged into the first and second plugs 52, 62. For example, if two vehicles requiring a charging power equal to three times the rated power of the power modules 18 are connected to the plugs 52, 62, then the power distribution unit 22 connects three power modules 18 to the first group and three power modules 18 to the second group, so that each vehicle can be charged as efficiently as possible. If a single electric vehicle is connected to one of the two plugs 52, 62 and requires a charging power equal to twice the rated power of the power modules, then the power distribution unit 22 connects two power modules 18 to the group corresponding to the plug that is used. In this example, the other four power modules are preferably allocated to the third group, so that the unused plug is not powered with direct current.

Thus, depending on the requirements, each of the first, second and third groups of power modules can comprise between zero and six power modules 18. The greater the number of power modules connected to a plug 52, 62, the greater the electric power that can be delivered by this plug to an electric vehicle.

Preferably, the positive polarity cable 42 of the first conductor 40 comprises a fuse 70 and the positive polarity cable 48 of the second conductor 46 comprises a fuse 71. The fuses 70, 71 allow the first and second conductors and the first and second plugs 52, 62 to be protected in the event of a fault in the charging station system 10 resulting in the flow of a direct current with greater power than the maximum power that can be supported by the conductors and plugs.

Preferably, the positive polarity cable 42 and the negative polarity cable 44 of the first conductor 40 comprise an isolation component 72A and an isolation component 72B, respectively. The isolation components 72A, 72B can be operated between an open position, in which the flow of a voltage and a current in the first conductor is prevented, and a closed position, in which the flow of a voltage and a current in the first conductor is not prevented. Thus, in the open position of the isolation components, the first plug 52 is isolated from the first group of power modules. The isolation components 72A, 72B can be used, for example, to interrupt the flow of direct current delivered by the first group of power modules to the first plug 52 when an incident is detected when charging an electric vehicle connected to the first plug. Similarly, the positive polarity cable 48 and the negative polarity cable 50 of the second conductor 46 include an isolation component 73A and an isolation component 73B, respectively.

Preferably, the charging station system 10 further comprises a first isolation control device 74, connected to the positive polarity cable 42 and to the negative polarity cable 44 of the first conductor 40, as well as to an earth plug 76, and also comprises a second isolation control device 78, connected to the positive polarity cable 48 and to the negative polarity cable 50 of the second conductor 46, as well as to an earth plug 80. Each isolation control device 74, 78 is capable of computing an impedance value between the associated positive polarity cable and the associated earth plug, between the associated negative polarity cable and the associated earth plug, and/or between the associated positive polarity cable and the associated negative polarity cable.

In order to compute an impedance value between a positive polarity cable and a negative polarity cable, an isolation control device injects a test signal into the positive polarity cable and measures the return signal induced by this test signal on the negative polarity cable. If the isolation between the negative and positive polarity cables was perfect, no return signal would be measured. In reality, this isolation is always imperfect, so a low-amplitude return signal is measured, even when the isolation is satisfactory. Then, an impedance value between the positive and negative polarity cables is computed based on the transmitted test signal and the measured return signal. Preferably, the transmitted test signal is a high-frequency signal, for example, between 1 kHz and 500 kHz (kilohertz). Preferably, an impedance value representing good isolation between the positive and negative polarity cables is greater than 250 kΩ (kiloohm).

An impedance value between a positive polarity cable and an earth plug, or between a negative polarity cable and an earth plug, is computed in the same way, by transmitting the test signal in the positive or negative polarity cable and measuring the return signal on the earth plug, or even by transmitting the test signal on the earth plug and measuring the return signal in the positive or negative polarity cable.

The isolation control devices 74, 78 thus allow the integrity of the isolation of the first and second conductors 40, 46 to be checked, by detecting any drop in impedance indicating a degradation in the isolation. For example, if an impedance of less than 250 kQ is computed between a positive polarity cable and a negative polarity cable, then the isolation between the positive and negative polarity cables is defective. In particular, an impedance of less than 50 kQ represents a cable with significantly degraded isolation.

The isolation control device 74 is located downstream of the isolation components 72A, 72B, i.e., it is located between the isolation components and the first plug 52. Similarly, the isolation control device 78 is located downstream of the isolation components 73A, 73B.

Preferably, the charging station system 10 further comprises a first electricity meter 82 connected to the positive polarity cable 42 and to the negative polarity cable 44 of the first conductor 40, and a second electricity meter 84 connected to the positive polarity cable 48 and to the negative polarity cable 50 of the second conductor 46.

In practice, each electricity meter 82, 84 comprises a voltmeter and an ammeter, and is therefore capable of measuring the voltage and the intensity of the direct current flowing in the respective conductor 40, 46.

The charging station system 10 further comprises a first control unit 86, associated with the first plug 52, and a second control unit 88, associated with the second plug 62. Each control unit 86, 88 controls the operation of the associated plug.

Furthermore, the control units 86, 88 are each connected to the power distribution unit 22. In the example, these connections are made by means of the first and second conductors 40, 46, by sending power line carrier modulation communication signals. As an alternative embodiment, the connections between the control units 86, 88 and the power distribution unit 22 are made by means of dedicated communication wires, which are either integrated into the first and second conductors, or are even separate from the first and second conductors, or by means of wireless links.

Similarly, the control units 86, 88 are each connected to the power modules 18.

Preferably, the first plug 52 comprises communication means 90, which are connected to the first control unit 86, and the second plug 62 comprises communication means 92, which are connected to the second control unit 88. These communication means 90, 92 are designed, when a plug is electrically connected to an electric vehicle, to allow communication between an electric vehicle and the control unit associated with said plug.

When the first control unit 86 detects that an electric vehicle is connected to the first plug 52, notably by virtue of the communication means 90, then the first control unit 86 assesses the electric power required for charging the electric vehicle, controls the power distribution unit 22 so as to allocate power modules 18 to the first group of power modules, by controlling the groups of relays 36, and controls the power modules of the first group of power modules so that they deliver a direct current with intensity and voltage that are suitable for charging the electric vehicle. Preferably, the first control unit 86 communicates with the electric vehicle by transmitting communication signals, thus allowing the correct progress of the charging of the electric vehicle to be monitored. These communication signals include, for example, information concerning the operation of the electric vehicle and of the charging station system 10. The operation of the second control unit 88 is similar to that of the first control unit 86.

Advantageously, the control units 86, 88 are respectively connected to the isolation control devices 74, 78, and to the electricity meters 82, 84. Thus, the impedance computations carried out by the isolation control devices and the measurements carried out by the electricity meters are collected and analysed by the corresponding control units.

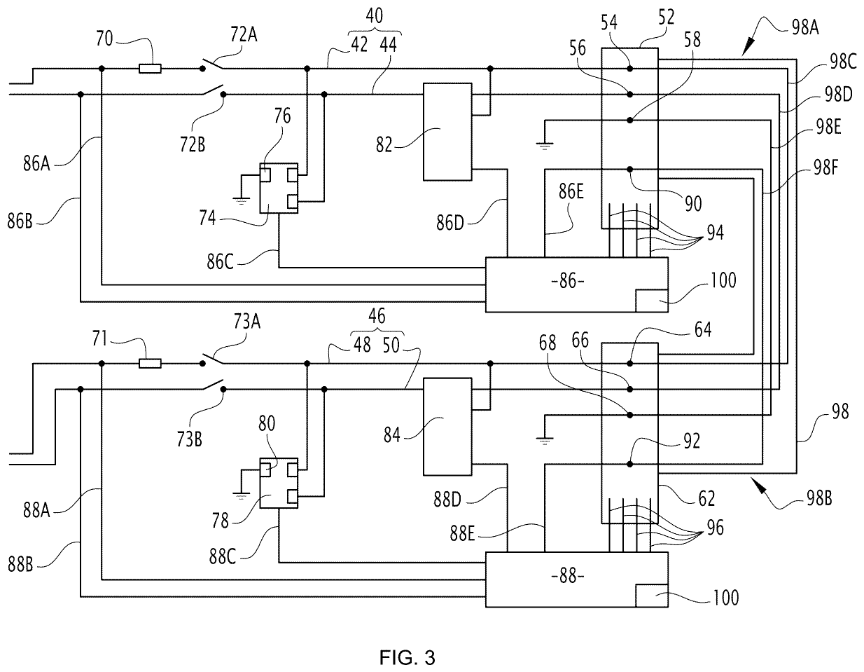

In FIGS. 1 and 3, the control units 86, 88 are shown separate from the plugs 52, 62 and the conductors 40, 46. Thus, the first control unit 86 is shown connected to the cables 42 and 44 of the first conductor by wires 86A, 86B, connected to the first isolation control device 74 by a wire 86C, connected to the first electricity meter 82 by a wire 86D and connected to the communication means 90 of the first plug 52 by a wire 86E. Similarly, the second control unit 88 is shown connected to the cables 48, 50 of the second conductor by wires 88A, 88B, connected to the second isolation control device 78 by a wire 88C, connected to the second electricity meter 84 by a wire 88D and connected to the communication means 92 of the second plug 62 by a wire 88E. As an alternative embodiment, the control units 86, 88 are directly integrated into the plugs 52, 62, or are mounted directly on the conductors 40, 46.

Advantageously, the first plug 52 comprises four temperature sensors 94. Among the four temperature sensors, two measure the temperature of the first plug at the positive connection point 54, and two measure the temperature of the first plug at the negative connection point 56. Thus, the temperature measurements are redundant, which allows any failure of a temperature sensor to be detected. The four temperature sensors 94 are connected to the first control unit 86, allowing the first control unit to collect the temperature measurements. Similarly, the second plug 62 comprises four temperature sensors 96, which are connected to the second control unit 88.

A diagnostic method for the charging station system 10 will now be described, which method aims to test the charging station system so as to check that it is operating correctly. This diagnostic method is implemented when no electric vehicle is connected to the plugs 52, 62.

The diagnostic method comprises a first connection step, which involves connecting the first plug 52 to the second plug 62, and more specifically connecting the positive connection point 54 of the first plug with the positive connection point 64 of the second plug, connecting the negative connection point 56 of the first plug with the negative connection point 66 of the second plug, connecting the earth connection point 58 of the first plug with the earth connection point 68 of the second plug, and, preferably, connecting the communication means 90 of the first plug 52 to the communication means 92 of the second plug 62, so as to form a loop comprising:
the first and second plugs;
the first and second conductors;
the power distribution unit 22; and
the first and second groups of power modules.

In a particularly advantageous manner, in order to connect the first plug 52 with the second plug 62, the charging station system 10 comprises dedicated connection means. In the example, these connection means are formed by a connection tool 98. The connection tool 98 is in the form of a cable or a casing, for example. It has a first female end fitting 98A adapted to be connected to the first plug 52, and a second female end fitting 98B adapted to be connected to the second plug 62.

In practice, the connection tool 98 comprises:
a positive cable 98C, which connects the positive connection point 54 of the first plug 52 to the positive connection point 64 of the second plug 62;
a negative cable 98D, which connects the negative connection point 56 of the first plug 52 to the negative connection point 66 of the second plug 62; and
an earth cable 98E, which connects the earth connection point 58 of the first plug 52 to the earth connection point 68 of the second plug 62; and
preferably, a communication cable 98F, which connects the communication means 90 of the first plug 52 to the communication means 92 of the second plug 62.

The diagnostic method then comprises a testing step, which involves transmitting at least one electric quantity flowing at least from the first plug 52 to the second plug 62 and involves measuring operating states of at least some of the elements of the loop in response to the transmitted electric quantity.

The diagnostic method then comprises an analysis step, which involves diagnosing said components on the basis of the measurements of the operating states.

This diagnostic method allows various components of the charging station system 10 to be diagnosed as a function of the one or more electric quantities transmitted during the testing step, and as a function of the one or more diagnostics carried out during the analysis step.

A first diagnostic that can be carried out by virtue of the diagnostic method is a simultaneous diagnostic of the integrity of the isolation of the first and second conductors 40, 46 and of the reliability of the isolation control devices 74, 78.

The testing step comprises an opening phase, during which the isolation components 73A and 73B are kept in the open position, so that the second plug 62 is isolated from the second group of power modules.

In order to carry out this first diagnostic, the testing step comprises, during the opening phase, the first isolation control device 74 transmitting a test signal in the first conductor 40 to the first plug 52. This test signal is established in the first and second conductors 40, 46, in the first and second plugs 52, 62 and in the connection tool 98.

Then, during the analysis step, the diagnostic is carried out by comparing:
a) an impedance value between the positive polarity cable 42 of the first conductor and the earth plug 76 of the first isolation control device 74 with an impedance value between the positive polarity cable 48 of the second conductor 46 and the earth plug 80 of the second isolation control device 78, with the impedance values being computed during the opening phase by the first and second isolation control devices on the basis of the test signal; and/or
b) an impedance value between the negative polarity cable 44 of the first conductor and the earth plug 76 of the first isolation control device 74 with an impedance value between the negative polarity cable 50 of the second conductor 46 and the earth plug 80 of the second isolation control device 78, with the impedance values being computed during the opening phase by the first and second isolation control devices; and/or
c) an impedance value between the positive 42 and negative 44 polarity cables of the first conductor with an impedance value between the positive 48 and negative 50 polarity cables of the second conductor 46, with the impedance values being computed during the opening phase by the first and second isolation control devices,
with the impedance values being computed by the isolation control devices based on the transmitted test signal and the measured feedback signal, as described above.

In practice, if the impedance values computed by the first isolation control device 74 are identical, or substantially identical, to the impedance values computed by the second isolation control device 78, then the operation of the first and second isolation control devices is considered to be reliable. Indeed, a failure of one of the two isolation control devices would result in a discrepancy between their impedance value computations.

Furthermore, if the impedance values a) computed by the first and second isolation control devices 74, 78 are substantially identical and close to a predetermined threshold value, then the integrity of the isolation of the first and second conductors between their positive polarity cables and earth is considered to be preserved. In the event of a significant difference between the impedance values a) and the predetermined threshold value, the isolation of the first conductor and/or of the second conductor is considered to be degraded, and more extensive examination of the first and second conductors is considered to be required in order to carry out a repair or replacement. Similarly, the impedance values b) are used to check the integrity of the isolation of the first and second conductors between their negative polarity cables and earth, and the impedance values c) are used to check the integrity of the isolation of the first and second conductors between their positive polarity cables and their negative polarity cables.

The first diagnostic also can be carried out by opening the isolation components 72A and 72B and causing a test signal to be transmitted to the second isolation control device 78.

In summary, during the first diagnostic, the transmitted electric quantity is a test signal transmitted by the first isolation control device 74 and the measured operating states are impedance values, computed on the basis of the test signal and a feedback signal induced by the test signal.

A second diagnostic that can be carried out by virtue of the diagnostic method is a diagnostic of the correct operation of the isolation components 73A and 73B. In order to carry out this second diagnostic, at least one power module 18 is associated with the first group of power modules and at least one power module 18 is associated with the second group of power modules.

During this second diagnostic, the testing step includes an opening phase, during which the isolation components 73A and 73B are kept in the open position, so that the second plug 62 is isolated from the second group of power modules. The opening phase of the second diagnostic can be the same opening phase as that of the first diagnostic, or even a different opening phase to that of the first diagnostic.

In order to carry out this first diagnostic, the testing step comprises, during the opening phase, the first group of power modules transmitting a DC/DC voltage to the first plug 52. This voltage is established in the first and second conductors 40, 46, in the first and second plugs 52, 62 and in the connection tool 98. This voltage is called “no load” voltage, as no electric load is connected to the first group of power modules.

When the opening phase of the second diagnostic is the same opening phase as that of the first diagnostic, the direct voltage is sent either at the same time as the test signal or at a later time.

Then, during the opening phase of the testing step, a voltage measurement is carried out at the output terminals of the power module belonging to the second group, with this measurement being carried out by the voltmeter installed in the power module.

Then, during the analysis step, a check is carried out to determine whether the voltage measured during the opening phase at the output terminals of the power module is zero or substantially zero. If this voltage is zero or substantially zero, then no voltage leakage is considered to exist through the isolation components 73A and 73B, and therefore the isolation components are considered to be working properly. Otherwise, the operation of the isolation components 73A and 73B is considered to be faulty and that they need to be repaired or replaced.

The second diagnostic also can be carried out in order to test the operation of the isolation components 72A and 72B, by opening the isolation components 72A and 72B and by causing a voltage to be transmitted to the second group of power modules, which then comprises at least one power module 18.

In summary, during the second diagnostic, the transmitted electric quantity is a voltage transmitted by the first group of power modules and the measured operating states are voltage values.

A third diagnostic that can be carried out by virtue of the diagnostic method is a diagnostic of the integrity of the isolation components 73A and 73B.

During this third diagnostic, each of the first and second groups of power modules comprises at least one power module 18. Furthermore, the testing step comprises a closing phase, during which the isolation components 73A and 73B are kept in the closed position, so that the second plug 62 is connected to the second group of power modules.

In order to carry out this third diagnostic, the testing step comprises, during the closing phase, the first group of power modules transmitting a direct voltage to the first plug 52. This voltage is established in the first and second conductors 40, 46, in the first and second plugs 52, 62 and in the connection tool 98, and flows in the loop to the second group of power modules.

Then, during the closing phase of the testing step, a voltage measurement is carried out at the output terminals of the power module belonging to the second group, with this measurement being carried out by the voltmeter installed in the power module, and a voltage measurement is carried out at the second conductor 46, with this measurement being carried out by the second electricity meter 84.

Then, during the analysis step, the diagnostic is carried out by comparing the voltage measured by the voltmeter of the power module 18 during the closing phase with a voltage measured by the second electricity meter 84 during the closing phase. If these two voltages are equal or substantially equal, then the integrity of the isolation components 73A and 73B is considered to be preserved, as they do not act as resistors when they are in the closed position. Otherwise, the operation of the isolation components 73A and 73B is considered to be faulty and that they need to be repaired or replaced.

The third diagnostic also can be carried out in order to test the operation of the isolation components 72A and 72B, by measuring the voltage on either side of the isolation components 72A and 72B during the closing phase, using the voltmeter installed in the power modules of the first group of power modules and using the first electricity meter 82.

The second and third diagnostics thus complement each other in order to check that the isolation components 72A, 72B, 73A, 73B are operating correctly, i.e., to check that they are operating correctly in the open position, i.e., that they completely interrupt a flow of current, and that they are operating correctly in the closed position, i.e., that they allow a flow of current without resisting said flow.

In summary, during the third diagnostic, the transmitted electric quantity is a voltage transmitted by the first group of power modules and the measured operating states are voltage values.

A fourth diagnostic that can be carried out using the diagnostic method is a diagnostic of the integrity of the communication means 90, 92 of the first and second plugs 52, 62.

In order to carry out this fourth diagnostic, the power modules 18 do not need to be assigned to the first and second groups of power modules.

In this fourth diagnostic, the testing step comprises a communication phase, during which a communication signal is transmitted by the first control unit 86, with this first communication signal then flowing via the first and second plugs 52, 62 and via the connection tool 98 to the second control unit 88.

Then, during the analysis step, the integrity of the communication means 90, 92 is checked using the following methods.

A first method involves comparing the communication signal sent by the first control unit with the communication signal received by the second control unit. This first method allows a possible degradation or loss of the communication signal transmitted by the first and second plugs 52, 62 to be detected, and therefore determines whether the replacement or repair of the communication means 90, 92 is necessary.

A second method involves the first control unit 86 transmitting a communication signal calling for a response, and analysing a response signal transmitted by the second control unit 88 in response to the reception of the communication signal. This second method allows a possible failure of the communication means 90, 92, but also of the second control unit 88, to be detected, notably in the event that a response signal is received by the first control unit 86, but does not correspond to the signal that should have been transmitted by the second control unit 88. For example, the transmitted communication signal corresponds to a signal transmitted by an electric vehicle in the event of a fault occurring while it is charging, which allows a check to be carried out to determine that the second control unit 88 actually receives this fault signal, and properly responds following the reception of this signal.

The fourth diagnostic can be carried out using either of these methods, or even by using both of these methods.

The second method has the advantage of allowing more extensive testing of the charging station system 10. For example, the communication signal transmitted by the first control unit 86 can simulate the operation of an electric vehicle, so as to make the second control unit 88 believe that an electric vehicle is being charged. Thus, it is possible to test the behaviour of the second control unit 88 when charging an electric vehicle, without having to actually charge an electric vehicle.

Furthermore, the communication signal transmitted by the first control unit 86 can simulate faults that can occur when charging an electric vehicle, so as to analyse the behaviour of the second control unit 88 when such a fault is detected. For example, it is possible to simulate a high battery temperature in an electric vehicle, an overcurrent fault in the battery of an electric vehicle, or even a fault in locking the first plug 52 on an electric vehicle.

The fourth diagnostic also can be carried out in order to test the operation of the first control unit 86, by causing the second control unit 88 to transmit the communication signal and analysing it in accordance with the second method.

In summary, during the fourth diagnostic, the transmitted electric quantity is a communication signal transmitted by the first control unit 86 and the measured operating states are signals received by the control units 86, 88 in response to this communication signal.

A fifth diagnostic that can be carried out by virtue of the diagnostic method is a diagnostic of the reliability of the electricity meters 82, 84.

During this fifth diagnostic, the first and second groups of power modules each comprise at least one power module 18. For example, each of the first and second groups of power modules comprises three power modules. Furthermore, the isolation components 72A, 72B, 73A and 73B are kept in the closed position.

In order to carry out this fifth diagnostic, the testing step comprises a current flow phase, during which the first group of power modules transmits a direct current, which flows in the loop to the second group of power modules. The current thus received by the second group of power modules is then converted into alternative current by the second group of power modules.

During the current flow phase, the voltage and the intensity of the direct current flowing in the first and second conductors 40, 46 are measured by the electricity meters 82, 84, respectively.

Then, during the analysis step, the voltage measured by the first electricity meter 82 is compared with the voltage measured by the second electricity meter 84, by checking whether the voltage measured by the first electricity meter is indeed equal, or substantially equal, to the inverse of the voltage measured by the second electricity meter. If this is the case, the voltmeters of the first and second electricity meters are considered to be working correctly. Otherwise, the voltmeter of the first electricity meter and/or the voltmeter of the second electricity meter are considered to be defective.

Similarly, during the analysis step, the intensity measured by the first electricity meter 82 is compared with the intensity measured by the second electricity meter 84, by checking whether the intensity measured by the first electricity meter is indeed equal, or substantially equal, to the inverse of the intensity measured by the second electricity meter. If this is the case, the ammeters of the first and second electricity meters are considered to be working correctly. Otherwise, the ammeter of the first electricity meter and/or the ammeter of the second electricity meter are considered to be defective.

Indeed, the direct current transmitted by the first group of power modules is transmitted to the second group of power modules by means of the conductors 40, 46 and the plugs 52, 62, without any significant consumption of energy taking place, as the loop does not include any electric load likely to consume energy. In practice, there are energy losses in the loop, notably linked to the Joule effect, but these losses are relatively small compared to the power that can be supplied by the first group of power modules. Consequently, if the electricity meters 82 and 84 are working correctly, the measurements of the first electricity meter are substantially equal to the inverse of the measurements of the second electricity meter.

In summary, during the fifth diagnostic, the transmitted electric quantity is a direct current, transmitted by the first group of power modules, and the measured operating states are voltage and intensity values.

A sixth diagnostic that can be carried out by virtue of the diagnostic method is a diagnostic of overheating of the first and second plugs 52, 62.

During this sixth diagnostic, the first and second groups of power modules each comprise at least one power module 18. For example, each of the first and second groups of power modules comprises three power modules. Furthermore, the isolation components 72A, 72B, 73A and 73B are kept in the closed position.

In order to carry out this sixth diagnostic, the testing step comprises a current flow phase, which is either the same as that of the fifth diagnostic, or is independent but identical to that of the fifth diagnostic. Thus, the sixth diagnostic can be carried out at the same time as, or independently of, the fifth diagnostic.

During the current flow phase, the temperature of the first and second plugs 52, 62 is measured by the temperature sensors 94, 96, respectively.

Then, during the analysis step, the temperature measurements carried out during the current flow phase are analysed in order to detect any overheating of the first and/or second plug. This analysis is carried out, for example, by comparing the temperature measurements with reference values, or by studying the evolution of the temperature measurements during the current flow phase, as a rapid rise in temperature can indicate overheating.

During the sixth diagnostic, it is also possible to monitor only the overheating of the first plug 52 or the second plug 62, by only carrying out temperature measurements with the corresponding temperature sensors 94, 96.

In summary, during the sixth diagnostic, the transmitted electric quantity is a direct current, transmitted by the first group of power modules, and the measured operating states are temperature values of the first and second plugs 52, 62.

A seventh diagnostic that can be carried out by virtue of the diagnostic method is a diagnostic of the overload resistance of the power modules of the second group of power modules.

During this seventh diagnostic, the second group of power modules comprises at least one power module 18, and the first group of power modules comprises at least two power modules 18, so that the first group comprises at least one more power module than the second group. For example, the first group of power modules comprises four power modules 18 and the second group of power modules comprises two power modules. Furthermore, the isolation components 72A, 72B, 73A and 73B are kept in the closed position.

In order to carry out this seventh diagnostic, the testing step comprises a current flow phase, which is either the same as that of the fifth and sixth diagnostics, or is independent but identical to those of the fifth and sixth diagnostics. Thus, the seventh diagnostic can be carried out at the same time as, or independently of, the fifth and sixth diagnostics.

The power modules of the first group of power modules are controlled so that, during the current flow phase, the electric power of the direct current flowing in the loop exceeds the rated power of the second group of power modules, i.e., the sum of the rated power of each of the power modules of the second group, by at least 5%, preferably by at least 10%.

For example, if the rated power of the power modules is equal to 30 kilowatts, if the first group comprises four power modules 18 and the second group comprises two power modules 18, then the first group of power modules transmits a direct current, the power of which is equal to 63 kilowatts, preferably equal to 66 kilowatts. It should be noted that this power is less than the maximum power delivered by the first group of power modules, which is equal to 120 kilowatts.

Thus, the power modules of the second group of power modules are overloaded.

Then, during the current flow phase, quantities characteristic of the operation of the power modules 18 of the second group of power modules are measured. This can involve, for example, temperature measurements carried out using temperature sensors integrated in the power modules, or even signals representing the correct operating state of power components integrated in the power modules 18, with these components being switching transistors or capacitors, for example.

Then, during the analysis step, the characteristic quantities measured during the current flow phase are analysed in order to detect a possible failure of the power modules in the second group of power modules. For example, if a temperature above a predetermined threshold is detected within one of the power modules, then this power module is considered to be unable to withstand an overload, and that a repair or replacement is necessary.

The seventh diagnostic also can be carried out in order to test the overload resistance of the power modules of the first group of power modules, by transmitting a direct current to the second group of power modules, the power of which is greater than the rated power of the first group of power modules.

In summary, during the seventh diagnostic, the transmitted electric quantity is a direct current, transmitted by the first group of power modules, and the measured operating states are quantities characteristic of the operation of the power modules 18 of the second group of power modules.

During the fifth, sixth and seventh diagnostics, the direct current received by the second group of power modules and converted into alternative current is either re-injected into the electric network or is fed to the first group of power modules by means of the distribution system 20.

In order to reduce the energy consumption of the diagnostic method, the alternative current produced by the second group of power modules based on the direct current received during the current flow phase of the testing step is preferably fed to the first group of power modules. Thus, the first group of power modules is essentially fed with alternative current by the second group of power modules. Due to the presence of energy losses in the loop, notably linked to the Joule effect, and to the imperfect efficiency of the power modules 18, not all the electric power of the direct current injected into the loop by the first group of power modules is recovered and then converted into alternative current by the second group of power modules. In practice, these losses amount to approximately 10%, preferably approximately 5%, of the alternative current consumed by the first group of power modules. In other words, the efficiency of the charging station system 10 during the current flow phase of the testing step is approximately 90%, preferably approximately 95%.

Thus, not all the electric power consumed by the first group of power modules can be supplied by the second group of power modules. The first group of power modules is then partially powered by the second group of power modules, and partially by the electric grid. In practice, given the efficiency described above, at least 90%, preferably at least 95%, of the electric power consumed by the first group of power modules is delivered to the first group of power modules by the second group of power modules. Thus, the consumption of electric energy originating from the electric grid is very low, and this consumption in practice is used to compensate for the losses of the charging station system 10.

This self-consumption is highly advantageous, since the electric energy consumed by the first group of power modules during the diagnostic method of the invention is not lost, unlike the electric energy consumed by the known diagnostic methods, in which this electric energy is lost when charging the battery of an electric vehicle, or is lost by the Joule effect in an electric load.

For this reason, another advantage of the invention is that it allows the correct operation of a charging station system to be diagnosed before this charging station system is connected to a high-power electric network, for example, before it is initially commissioned. Indeed, only a small amount of power originating from the electric network is required in order to execute the fifth, sixth and seventh diagnostics described above, and the first to fourth diagnostics described above do not require significant electric consumption by the charging station system in order to be implemented.

Furthermore, another advantage of the diagnostic method of the invention is that it allows endurance tests to be carried out on the charging station system 10, for example, by transmitting an electric current to the first group of power modules over a long period of time. Indeed, given the low energy consumption of the diagnostic method of the invention, such endurance tests can be carried out at a competitive cost, which is not the case with the known diagnostic methods, for which carrying out an endurance test would result in high energy consumption.

In addition, the diagnostic method of the invention is inexpensive to implement, as the connection tool 98 is particularly simple and inexpensive to manufacture, and the diagnostic method does not require the use of other equipment. Thus, the use of an electric load or an electric car with a discharged battery, as is the case in the known diagnostic methods, is avoided.

Furthermore, the diagnostic method can incorporate any combination of the diagnostics described above in several successive steps. Thus, by virtue of the invention, it is possible to diagnose most of the components of the charging station system 10 using a single method.

By virtue of the diagnostic method of the invention, other more complex diagnostics also can be carried out. For example, it is possible to fully simulate the operation of an electric vehicle being charged with the second group of power modules, which then simulates the energy consumption of the electric vehicle, and with the second control unit 88 and the communication means 92, which then simulates the communications and data of the electric vehicle. Thus, the first control unit 86 acts as if an electric vehicle is being charged, which allows diagnostics of all the elements of the loop from the first group of control units to the first plug 52 under conditions that are substantially identical to the real charging conditions of an electric vehicle. In other words, the diagnostic method of the invention allows a dialogue to be simulated between a charging station and an electric vehicle simply by connecting the first and second plugs 52, 62 to each other.

It is also possible to test some components of the charging station system 10 with dynamic tests, for example, by sending a voltage ramp and/or a current ramp to the first group of power modules during the testing step.

Advantageously, the first control unit 86 and/or the second control unit 88 comprises a control module 100 that executes the testing and analysis steps of the diagnostic method of the invention. In the example, each control module 100 is a processor, and will be referred to as such throughout the remainder of the description. As an alternative embodiment of the invention that is not shown, each control module 100 is a microprocessor, a PLC, an Application-Specific Integrated Circuit, more commonly referred to as ASIC, or even a reprogrammable integrated circuit, more commonly referred to as FPGA (Field-Programmable Gate Array).

In other words, the one or more electric quantities, such as a voltage, a current or a communication signal, transmitted by the first group of power modules and/or by the first control unit 86 are transmitted subject to an instruction from the processor 100 of the first control unit 86 or subject to an instruction from the processor 100 of the second control unit 88, and the one or more analyses carried out during the analysis step are carried out by this processor.

In other words, apart from the connection step, which requires a physical intervention on the charging station system 10, the diagnostic method is executed by the processor 100.

Preferably, the first to seventh diagnostics are stored in a memory accessible by the processor 100 in the form of instructions that can be executed by the processor. Thus, the diagnostic method is started, for example, using a control interface of the charging station system 10, or even using a communication interface, such as a connection with a remote computer or even with a computer connected to the charging station system. Alternatively, the instructions that allow the processor to execute the diagnostic method are directly sent to the processor 100 by a computer or by a remote server connected to the processor.

In an alternative embodiment of the invention that is not shown, the processor 100 executing the diagnostic method is installed in the power distribution unit 22, or in another location of the charging station system 10.

In an alternative embodiment of the invention that is not shown, the power modules 18 do not incorporate electricity meters, but the power unit 22 incorporates a first electricity meter capable of measuring a voltage and an intensity at the first output terminal 24, and a second electricity meter capable of measuring a voltage and an intensity at the second output terminal 30.

In an alternative embodiment of the invention that is not shown, the isolation components 72A, 72B, 73A and 73C are not integrated in the first and second conductors 40 and 46, but are integrated in the power unit 22, between the groups of relays 36 and the first and second output terminals 24, 30.

In an alternative embodiment of the invention that is not shown, the first and second plugs 52, 62 do not comprise an earth connection point 58, 68 and therefore are not connected to earth.

In an alternative embodiment of the invention that is not shown, the first and second plugs 52, 62 comprise a different number of temperature sensors 94, 96, for example, two temperature sensors per plug, with a first sensor measuring the temperature of the plug at the positive connection point, and a second sensor measuring the temperature of the plug at the negative connection point, or even a single temperature sensor per plug, measuring the temperature of a casing of the plug.

In an alternative embodiment of the invention that is not shown, the temperature sensors 94, 96 are not disposed in the first and second plugs 52, 62, but are integrated in the first and second conductors 40, 46. In this alternative embodiment, the temperature sensors are thus used to detect overheating of the conductors.

In an alternative embodiment of the invention that is not shown, the first and second plugs 52, 62 do not comprise dedicated communication means 90, 92, and the communications with the control units 86, 88 pass through the positive 54, 64 and negative 56, 66 connection points of the plugs by power line carrier modulation. In other words, in such an alternative embodiment, the communication means of the plugs are virtual and are formed by the power line carrier modulation communication signals passing through the plugs.

In an alternative embodiment of the invention that is not shown, the charging station system 10 does not comprise six power modules 18 but comprises, for example, four, five or eight power modules. In practice, the charging station system 10 comprises at least two power modules 18, so as to allow simultaneous charging of two electric vehicles.

In an alternative embodiment of the invention that is not shown, the charging station system 10 comprises a single control unit, which consolidates the first and second control units 86, 88.

In an alternative embodiment of the invention that is not shown, the charging station system 10 comprises more than two plugs, for example, three plugs or four plugs, thus allowing simultaneous charging of more than two electric vehicles, and comprises a corresponding number of conductors. In such an alternative embodiment, it is possible to diagnose the operation of all the associated plugs and connectors by successively carrying out the diagnostic method of the invention, by alternately connecting the plugs to each other in pairs.

In an alternative embodiment of the invention that is not shown, the charging station system 10 has a first female plug, which is connected to the first plug 52, and/or a second female plug, which is connected to the second plug 62. In such an alternative embodiment, the connection tool 98 is not required for the connection step of the diagnostic method, and this connection step is carried out by connecting the first plug 52 to the second female plug, or even by connecting the second plug 62 to the first female plug. Thus, in such an alternative embodiment, the connection means are formed by the first female plug and/or by the second female plug. Such an alternative embodiment is advantageous for facilitating the implementation of the diagnostic method, as it is thus possible to connect the plugs 52, 62 to each other without having to use a connection tool.

In the example, the charging station system 10 comprises a single charging station with two plugs 52, 62, thus allowing simultaneous charging of two electric vehicles. This architecture is advantageous because it allows the power modules 18 to be pooled and distributed as best as possible in the first and second groups of power modules, by virtue of the power distribution unit 22, according to requirements. The diagnostic method of the invention also can be used within the context of a charging station system comprising two separate charging stations. In such an alternative embodiment, a distinction is made between a first charging station, comprising a first plug, a first conductor, a first group of power modules and a first control unit, and a second charging station, comprising a second plug, a second conductor, a second group of power modules and a second control unit. Such a charging station system thus does not comprise a power distribution unit, since each charging station has its own one or more dedicated power modules. In such an alternative embodiment, the diagnostic method allows the first charging station to be used as a “master” station, which simulates the operation of an electric vehicle being charged and which contains the processor executing the diagnostic method, and allows the second charging station to be used as a “slave” station, which is then tested by the diagnostic method. Furthermore, in such a configuration, during the testing step of the diagnostic method, it is possible to control the master charging station so as to operate the slave charging station in the same way as when charging an electric vehicle.

In the example, the input terminal block 12 is connected to an electric network supplying the charging station system with alternative current. As an alternative embodiment, the input terminal block is connected to an electric network delivering a direct current to the charging station system. For example, the input terminal block is connected to an AC/DC converter belonging to the electric network. In such an alternative embodiment, the input terminal block 12, the circuit breaker 14, the input power switch 16 and the distribution system 20 are adapted to operate on direct current. Furthermore, in such an alternative embodiment, the power modules 18 are capable of converting a direct current originating from an electric network into a direct current delivered to the power distribution unit 22, and, preferably, of converting a direct current originating from the power distribution unit into a direct current delivered to the electric network. Thus, in this alternative embodiment, each power module 18 operates as a DC/DC converter.

In an alternative embodiment of the invention that is not shown, the control units 86 and 88 do not comprise a control module 100, and the charging station system 10 comprises a control module 100 for executing the testing and analysis steps of the diagnostic method of the invention, which control module is disposed at another location, such as, for example, within the power distribution unit 22.

In an alternative embodiment of the invention that is not shown, the control units 86 and 88 do not comprise a control module 100, and the charging station system 10 comprises a control module 100, for executing the testing and analysis steps of the diagnostic method of the invention, which is disposed remote from the plugs 52, 62, the conductors 40, 46, the power distribution unit 22 and the power modules 18 of the charging station system 10, i.e., which is remote. The control module 100 is integrated, for example, in a remote server, which is connected to the control units 86, 88 by a communication device, not shown. Thus, unlike the main mode of the invention, in which the control modules 100 are integrated in the control units 86, 88, i.e., they are physically connected to the plugs 52, 62 and to the conductors 40, 46, in such an alternative embodiment, the charging station system comprises, on the one hand, the one or more charging stations comprising the two plugs 52, 62, forming a set of elements physically connected together, and, on the other hand, the control module 100, which is remote, i.e., it is not physically connected to the plugs 52, 62 and to the conductors 40, 46, but is connected to the control units 86, 88 by a communication device.

Any feature described above for an embodiment or an alternative embodiment can be implemented for the other embodiments and alternative embodiments described above, insofar as this is technically feasible.

1. A diagnostic method for a charging station system for an electric vehicle, the charging station system comprising:
at least one first plug and one second plug, each plug comprising a positive connection point and a negative connection point, each plug being configured to allow an electric vehicle to be electrically connected to the charging station system and to allow the electric vehicle to be supplied with a direct current so as to charge the electric vehicle;
at least one first conductor, associated with the first plug, and one second conductor, associated with the second plug, each conductor comprising a positive polarity cable and a negative polarity cable; and
at least one first group of power modules associated with the first conductor and the first plug and one second group of power modules associated with the second conductor and the second plug, each group of power modules being capable of converting an alternative current or a direct current originating from an electric network into a direct current delivered to the associated plug by means of the associated conductor;
the diagnostic method comprising at least the following steps:
a connection step, involving connecting the positive connection point of the first plug with the positive connection point of the second plug and connecting the negative connection point of the first plug with the negative connection point of the second plug, so as to form a loop comprising at least:
the first and second plugs;
the first and second conductors; and
the first and second groups of power modules;
a testing step, involving transmitting at least one electric quantity flowing at least from the first plug to the second plug and measuring operating states of at least some of the elements of the loop in response to the transmitted electric quantity; and
an analysis step, involving diagnosing said elements on the basis of the measurements of the operating states.

2. The diagnostic method according to claim 1, wherein the charging station system further comprises:
a first isolation control device connected to the positive polarity cable and to the negative polarity cable of the first conductor, as well as to an earth plug, and capable of carrying out an impedance computation between:
said positive polarity cable and said earth plug;
said negative polarity cable and said earth plug; and/or
said positive polarity cable and said negative polarity cable; and
a second isolation control device connected to the positive polarity cable and to the negative polarity cable of the second conductor, as well as to an earth plug, and capable of carrying out an impedance computation between:
said positive polarity cable and said earth plug;
said negative polarity cable and said earth plug; and/or
said positive polarity cable and said negative polarity cable;
wherein the charging station system further comprises isolation components that are either disposed in the second group of power modules or are disposed in the second conductor between the second group of power modules and the second isolation control device,
wherein the isolation components can be operated between an open position, in which the flow of a voltage and a current between the second group of power modules and the second isolation control device is prevented, and a closed position, in which the flow of a voltage and a current between the second group of power modules and the second isolation control device is not prevented,
wherein the testing step further comprises an opening phase involving keeping the isolation components in the open position,
wherein the at least one electric quantity transmitted during the testing step comprises a test signal, transmitted during the opening phase by the first isolation control device in the first conductor and flowing in the loop to the isolation components, by means of the first plug and the second plug,
wherein, during the analysis step, a diagnostic of the integrity of the isolation of the first and second conductors and of the reliability of the first and second isolation control devices is carried out by comparing:
an impedance value between the positive polarity cable of the first conductor and the earth plug of the first isolation control device with an impedance value between the positive polarity cable of the second conductor and the earth plug of the second isolation control device, with the impedance values being computed during the opening phase by the first and second isolation control devices on the basis of the test signal; and/or
an impedance value between the negative polarity cable of the first conductor and the earth plug of the first isolation control device with an impedance value between the negative polarity cable of the second conductor and the earth plug of the second isolation control device, with the impedance values being computed during the opening phase by the first and second isolation control devices on the basis of the test signal; and/or
an impedance value between the positive and negative polarity cables of the first conductor with an impedance value between the positive and negative polarity cables of the second conductor, with the impedance values being computed during the opening phase by the first and second isolation control devices on the basis of the test signal.

3. The diagnostic method according to claim 1, wherein the charging station system comprises an upstream voltmeter, adapted to measure a voltage at the output terminals of the second group of power modules,
wherein the charging station system further comprises isolation components that are either disposed in the second group of power modules or are disposed in the second conductor between the second group of power modules and the second plug;
wherein the isolation components can be operated between an open position, in which the flow of a voltage and a current between the second group of power modules and the second plug is prevented, and a closed position, in which the flow of a voltage and a current between the second group of power modules and the second plug is not prevented,
wherein the testing step further comprises an opening phase involving keeping the isolation components in the open position,
wherein the at least one electric quantity transmitted during the testing step comprises a direct voltage, transmitted during the opening phase by the first group of power modules and flowing in the loop to the isolation components, by means of the first plug and the second plug,
wherein the testing step comprises, during the opening phase, a voltage measurement carried out by the upstream voltmeter, and
wherein the analysis step further comprises diagnosing the operation of the isolation components, carried out by checking whether the voltage measured by the upstream voltmeter during the opening phase is zero.

4. The diagnostic method according to claim 3, wherein the second conductor further comprises a downstream voltmeter, disposed between the isolation components and the second plug, adapted to measure a voltage between the positive polarity cable and the negative polarity cable of the second conductor,
wherein the testing step further comprises a closing phase involving keeping the isolation components in the closed position,
wherein the at least one electric quantity transmitted during the testing step further comprises a direct voltage, transmitted during the closing phase by the first group of power modules and flowing in the loop to the second group of power modules, by means of the first plug and the second plug, and
wherein, during the analysis step, a diagnostic of the integrity of the isolation components of the second conductor is carried out by comparing a voltage measured by the upstream voltmeter during the closing phase with a voltage measured by the downstream voltmeter during the closing phase.

5. The diagnostic method according to claim 1, wherein the charging station system further comprises at least one first control unit associated with the first plug and one second control unit associated with the second plug, each control unit controlling the operation of the associated plug,
wherein the first plug and the second plug each further comprise communication means connected to the associated control unit and configured so as to allow, when a plug is electrically connected to an electric vehicle, communication between an electric vehicle and the control unit associated with said plug,
wherein, during the connection step, the communication means of the first plug are connected to the communication means of the second plug,
wherein the at least one electric quantity transmitted during the testing step comprises a communication signal, transmitted by the first control unit and flowing to the second control unit by means of the first plug and the second plug, and
wherein, during the analysis step, a diagnostic of the integrity of the communication means of the first and second plugs and of the second control unit is carried out as follows:
by comparing the communication signal transmitted by the first control unit with the communication signal received by the second control unit; and/or
by analysing a response signal transmitted by the second control unit in response to the receipt of the communication signal.

6. The diagnostic method according to claim 1, wherein the first and second groups of power modules are further capable of converting direct current originating from the associated plug into alternative current or direct current suitable for being delivered to the electric network, and
wherein the at least one electric quantity transmitted during the testing step comprises a direct current, transmitted by the first group of power modules and flowing in the loop to the second group of power modules, by means of the first plug and the second plug, the direct current received by the second group of power modules being converted into an alternative current or into a direct current suitable for being delivered to the electric network.

7. The diagnostic method according to claim 6, wherein the charging station system further comprises an input power switch and a distribution system, the input power switch being configured to allow the distribution system to be connected to the electric network, and the distribution system being configured to connect the first and second groups of power modules to each other and to the input power switch, the second group of power modules also being capable of converting a direct current originating from the charging station system into an alternative current or into a direct current delivered to the first group of power modules,
wherein, during the testing step, the direct current received by the second group of power modules is converted by the second group of power modules into alternative current or into direct current delivered to the first group of power modules by means of the distribution system,
wherein, during the testing step, the first group of power modules is powered with alternative current or direct current by the second group of power modules and by the electric network, and
wherein at least 90% of the electric power consumed by the first group of power modules during the testing step is delivered to the first group of power modules by the second group of power modules.

8. The diagnostic method according to claim 6, wherein the charging station system further comprises:
a first electricity meter disposed between the first group of power modules and the first plug and adapted to measure a voltage and an intensity of the direct current flowing in the first conductor;
a second electricity meter disposed between the second group of power modules and the second plug and adapted to measure a voltage and an intensity of the direct current flowing in the second conductor; and
wherein the analysis step comprises a diagnostic of the reliability of the electricity meters, carried out by comparing voltage and intensity measurements carried out by the first electricity meter during the testing step with voltage and intensity measurements carried out by the second electricity meter during the testing step.

9. The diagnostic method according to claim 6, wherein the charging station system further comprises:
a first temperature sensor disposed on the first plug or on the first conductor; and/or
a second temperature sensor disposed on the second plug or on the second conductor; and
wherein the analysis step comprises diagnosing overheating, carried out by analysing temperature measurements carried out by the first temperature sensor and/or by the second temperature sensor during the testing step.

10. The diagnostic method according to claim 6, wherein, during the testing step, an electric power supplied by the first group of power modules to the second group of power modules by means of the direct current transmitted by the first group of power modules is at least 5% higher than a rated electric power of the second group of power modules, and wherein the analysis step comprises diagnosing the overload resistance of the second group of power modules, carried out by analysing quantities characteristic of the operation of the second group of power modules measured during the testing step.

11. A charging station system for an electric vehicle, comprising:
at least one first plug and one second plug, each plug comprising a positive connection point and a negative connection point, each plug being configured to allow an electric vehicle to be electrically connected to the charging station system and to allow the electric vehicle to be supplied with a direct current so as to charge the electric vehicle;
at least one first conductor, associated with the first plug, and one second conductor, associated with the second plug, each conductor comprising a positive polarity cable and a negative polarity cable; and
at least one first group of power modules associated with the first conductor and the first plug and one second group of power modules associated with the second conductor and the second plug, each group of power modules being capable of converting an alternative current or a direct current originating from an electric network into a direct current delivered to the associated plug by means of the associated conductor;
wherein the charging station system further comprises connection means adapted to connect the positive connection point of the first plug with the positive connection point of the second plug and to connect the negative connection point of the first plug with the negative connection point of the second plug,
and wherein the charging station system comprises a control module configured to execute the testing and analysis steps of the diagnostic method of claim 1.

12. The charging station system according to claim 11, wherein the control module is physically connected to the first plug and/or to the second plug,
or wherein the control module is integrated in a remote server.

13. The charging station system according to claim 11, wherein the connection means are formed by a connection tool, such as a cable or a casing, having a first female end fitting adapted to be connected to the first plug and having a second female end fitting adapted to be connected to the second plug.

14. The charging station system according to claim 11, comprising a single charging station comprising:
at least two power modules, each power module being capable of converting an alternative current or a direct current originating from the electric network into a direct current delivered to the charging station system;
at least one power distribution unit:
comprising at least one first output terminal connected to the first conductor and one second output terminal connected to the second conductor;
an output of each of the power modules being electrically coupled to the power distribution unit;
the distribution unit being configured to be switchable so that each power module is either connected to the first output terminal or is connected to the second output terminal, or is isolated from the first and second output terminals;
wherein the one or more power modules connected to the first output terminal form the first group of power modules, and
wherein the one or more power modules connected to the second output terminal form the second group of power modules.

15. The charging station system according to claim 11, comprising:
a first charging station comprising the first plug, the first conductor and the first group of power modules; and
a second charging station separate from the first charging station, comprising the second plug, the second conductor and the second group of power modules.
